(19) United States
(12) Patent Application Publication
(10) Pub. No.: US 2025/0372455 A1
(43) Pub. Date: Dec. 4, 2025

(54) METHODS OF IMAGING A WIRE STRUCTURE ON A WIRE BONDING SYSTEM

(71) Applicant: Kulicke and Soffa Industries, Inc., Fort Washington, PA (US)

(72) Inventors: Basil Milton, Furlong, PA (US); Vladimir Pribula, Norristown, PA (US); Aishwarya Abhay Panchpor, Princeton, NJ (US); Odal Kwon, Blue Bell, PA (US)

(73) Assignee: Kulicke and Soffa Industries, Inc., Fort Washington, PA (US)

(21) Appl. No.: 19/181,122

(22) Filed: Apr. 16, 2025

Related U.S. Application Data
(60) Provisional application No. 63/637,321, filed on Apr. 22, 2024.

(51) Int. Cl. H01L 21/66; H01L 23/00

(52) U.S. Cl. CPC H01L 22/12; H01L 24/78; H01L 2224/78901

(57) ABSTRACT

A method of imaging a wire structure on a wire bonding system is provided. The method includes the steps of: (a) forming the wire structure at a bonding location of a workpiece on the wire bonding system, the wire structure including a bonded portion bonded to the bonding location, and a free end continuous with the bonded portion; and (b) imaging a portion of the wire structure on the wire bonding system using a plurality of distinct focal planes.

### CROSS-REFERENCE TO RELATED APPLICATION

This application claims the benefit of U.S. Provisional Application No. 63/637,321, filed on Apr. 22, 2024, the content of which is herein incorporated by reference.

### FIELD

The invention relates to wire bonding operations, and in particular, to methods of imaging a wire structure on a wire bonding system.

### BACKGROUND

In the processing and packaging of semiconductor devices, wire bonding continues to be the primary method of providing electrical interconnection between two locations within a package (e.g., between a die pad of a semiconductor die and a lead of a leadframe). More specifically, using a wire bonder (also known as a wire bonding system) wire structures such as wire loops are formed between respective locations to be electrically interconnected. The primary methods of forming wire loops are ball bonding and wedge bonding. In forming the bonds between (a) the ends of the wire loop and (b) the bond site (e.g., a die pad, a lead, etc.) varying types of bonding energy may be used, including, for example, ultrasonic energy, thermosonic energy, thermocompressive energy, amongst others. Wire bonding systems (e.g., stud bumping machines) are also used to form other types of wire structures such as conductive bumps, for example, on workpieces such as semiconductor wafers.

Wire bonding systems are also used to form wire structures (e.g., wire interconnect structures, shielding structures, etc.) having a bonded portion and a free end. Examples of such uses of wire bonding systems are disclosed in U.S. Pat. No. 9,502,371 (“METHODS OF FORMING WIRE INTERCONNECT STRUCTURES”), U.S. Pat. No. 9,865,560 (“METHODS OF FORMING WIRE INTERCONNECT STRUCTURES”), U.S. Pat. No. 10,153,247 (“METHODS OF FORMING WIRE INTERCONNECT STRUCTURES”), U.S. Pat. No. 12,057,431 (“METHODS OF FORMING WIRE INTERCONNECT STRUCTURES AND RELATED WIRE BONDING TOOLS”), and U.S. Patent Application Publication No. 2024/0363583 (“METHODS OF FORMING WIRE INTERCONNECT STRUCTURES AND RELATED WIRE BONDING TOOLS”).

In forming wire loops and other wire structures, it is important that certain aspects of the wire structure (e.g., a height of a wire structure) be consistently formed. For example, PCT International Publication Number WO 2009/002345 (“METHOD OF DETERMINING A HEIGHT PROFILE OF A WIRE LOOP ON A WIRE BONDING MACHINE”) discloses using a vision system to detect the edges of a portion of a wire structure, and then using the location of the edges to control a free air ball to contact the wire to determine the height of the wire loop.

It would be desirable to provide improved methods of imaging wire structures on wire bonding systems.

### SUMMARY

According to an exemplary embodiment of the invention, a method of imaging a wire structure on a wire bonding system is provided. The method includes the steps of: (a) forming the wire structure at a bonding location of a workpiece on the wire bonding system, the wire structure including a bonded portion bonded to the bonding location, and a free end continuous with the bonded portion; and (b) imaging a portion of the wire structure on the wire bonding system using a plurality of distinct focal planes.

According to an exemplary embodiment of the invention, a method of detecting the presence or absence of a wire structure on a wire bonding system is provided. The method includes the steps of: (a) forming the wire structure at a bonding location of a workpiece on the wire bonding system, the wire structure being configured to include a bonded portion bonded to the bonding location, and a free end continuous with the bonded portion; (b) imaging a portion of the wire structure on the wire bonding system using a plurality of distinct focal planes; and (c) varying the focal plane if the desired portion of the wire structure is not located during the imaging of step (b) and repeating the imaging. The focal plane may be varied multiple times (and the imaging repeated), for example, until: (i) the portion of the wire structure is located through an imaging operation; (ii) a predetermined number of focal planes, or a range of expected heights of the portion of the wire structure (or a range of xy locations), have been used without locating the portion of the wire structure; and/or (iii) the portion of the wire structure (or the entire wire structure) is declared missing.

According to other embodiments of the invention, the methods recited in the immediately two preceding paragraphs (and/or the method recited in the immediately subsequent paragraph) may have any one or more of the following features: step (b) includes imaging the free end of the wire structure; step (b) includes imaging the bonded portion of the wire structure; step (b) includes imaging a plurality of portions of the wire structure, each of the plurality of portions being imaged at a subset of the plurality of distinct focal planes; further including a step of assembling a digital representation of the wire structure using results of step (b); step (b) includes imaging the free end of the wire structure and imaging the bonded portion of the wire structure; step (b) includes imaging at least one portion of the wire structure between (i) the bonded portion of the wire structure and (ii) the free end of the wire structure; further including step (c) determining if a position of the portion of the wire structure imaged in step (b) is acceptable; the position of the portion of the wire structure includes an x-y position; the position of the portion of the wire structure includes a z-axis position; an adjustment is made to at least one of (i) a wire bonding parameter and (ii) a wire looping parameter, if it is determined that the position of the portion of the wire structure is not acceptable at step (c); steps (a), (b), and (c) are repeated after the adjustment is made; the portion of the wire structure is the free end of the wire structure, and an adjustment is made to at least one of a wire looping parameter and a wire bonding parameter if it is determined that the position of the free end of the wire structure is not acceptable; the portion of the wire structure is the bonded portion of the wire structure, and wherein an adjustment is made to a wire bonding parameter if it is determined that the position of the bonded portion of the wire structure is not acceptable; step (b) includes imaging the portion of the wire structure at a first focal plane of the wire bonding system, the first focal plane being coincident with an expected height of the portion of the wire structure; step (b) includes imaging the portion of the wire structure at a second focal plane of the wire bonding system if results of imaging of the portion are not acceptable at the first focal plane; further including a step of determining a height of the wire structure; the step of determining the height of the wire structure is determined using results of step (b); the step of determining the height of the wire structure is determined by contacting the free end of the wire structure using a free air ball positioned at an end of a wire bonding tool used to form the wire structure; step (b) includes performing the imaging using a camera positioned above the wire structure, the camera being carried by a bond head assembly of the wire bonding system; step (b) includes performing the imaging using a camera positioned above the wire structure and at least one optical element for imaging a side portion of the wire structure; and/or step (b) includes performing the imaging using a plurality of cameras on the wire bonding system.

According to an exemplary embodiment of the invention, a method of imaging wire structures on a wire bonding system is provided. The method includes the steps of: (a) forming a plurality of wire structures at respective bonding locations of a workpiece on the wire bonding system, each of the plurality of wire structures including a bonded portion bonded to one of the bonding locations, and a free end continuous with the bonded portion; and (b) imaging simultaneously a portion of each of the plurality of wire structures on the wire bonding system.

According to other embodiments of the invention, the method recited in the immediately preceding paragraph may have any one or more of the following features: step (b) includes imaging the free end of each of the plurality of wire structures; step (b) includes imaging the bonded portion of each of the plurality of wire structures; step (b) includes imaging a plurality of portions of each of the plurality of wire structures; step (b) includes (b1) imaging the bonded portion of each of the plurality of wire structures at a first focal plane of the wire bonding system, and (b2) imaging the free end of each of the plurality of wire structures at a second focal plane of the wire bonding system; the plurality of wire structures are included in a single field of view of the wire bonding system; further including step (c) determining if a position of the portion of each of the wire structures imaged in step (b) is acceptable; and/or step (a) is repeated for another workpiece, and for at least one of a plurality of wire structures of the another workpiece an adjustment is made to at least one of (i) a wire bonding parameter and (ii) a wire looping parameter.

According to an exemplary embodiment of the invention, a method of imaging wire structures on a wire bonding system is provided. The method includes the steps of: (a) forming the wire structure at a bonding location of a workpiece on the wire bonding system, the wire structure including a bonded portion bonded to the bonding location, and a free end continuous with the bonded portion; (b) imaging a portion of the wire structure on the wire bonding system; and (c) determining a height of the wire structure using image processing of results of step (b).

According to other embodiments of the invention, the method recited in the immediately preceding paragraph may have any one or more of the following features: step (b) includes imaging the free end of the wire structure; step (b) includes imaging the bonded portion of the wire structure; step (b) includes imaging a plurality of portions of the wire structure; further including a step of assembling a digital representation of the wire structure using results of step (b); step (b) includes imaging the free end of the wire structure and imaging the bonded portion of the wire structure; step (b) includes imaging at least one portion of the wire structure between (i) the bonded portion of the wire structure and (ii) the free end of the wire structure; further including step (d) determining if a position of the portion of the wire structure imaged in step (b) is acceptable; the position of the portion of the wire structure is an x-y position; an adjustment is made to at least one of (i) a wire bonding parameter and (ii) a wire looping parameter, if it is determined that the position of the portion of the wire structure is not acceptable at step (d); steps (a), (b), and (c) are repeated after the adjustment is made; the portion of the wire structure is the free end of the wire structure, and wherein an adjustment is made to at least one of a wire looping parameter and a wire bonding parameter if it is determined that the position of the free end of the wire structure is not acceptable; the portion of the wire structure is the bonded portion of the wire structure, and wherein an adjustment is made to a wire bonding parameter if it is determined that the position of the bonded portion of the wire structure is not acceptable; step (b) includes imaging the portion of the wire structure at a first focal plane of the wire bonding system, the first focal plane being coincident with an expected height of the portion of the wire structure; step (b) includes imaging the portion of the wire structure at a second focal plane of the wire bonding system if results of imaging of the portion are not acceptable at the first focal plane; step (a) includes forming a plurality of the wire structures at respective bonding locations of the workpiece, and step (b) includes imaging a portion of each of the plurality of the wire structures on the wire bonding system; step (b) includes performing the imaging using a camera positioned above the wire structure, the camera being carried by a bond head assembly of the wire bonding system; step (b) includes performing the imaging using a camera positioned above the wire structure and at least one optical element for imaging a side portion of the wire structure; and/or step (b) includes performing the imaging using a plurality of cameras on the wire bonding system.

According to an exemplary embodiment of the invention, a method of imaging wire structures on a wire bonding system is provided. The method includes the steps of: (a) forming the wire structure at a bonding location of a workpiece on the wire bonding system, the wire structure including a bonded portion bonded to the bonding location, and a free end continuous with the bonded portion; (b) imaging a portion of the wire structure on the wire bonding system; (c) determining if a position of the portion of the wire structure imaged in step (b) is acceptable; and (d) adjusting at least one of (i) a wire bonding parameter and (ii) a wire looping parameter if it is determined that the position of the portion of the wire structure is not acceptable.

According to other embodiments of the invention, the method recited in the immediately preceding paragraph may have any one or more of the following features: step (b) includes imaging the free end of the wire structure; step (b) includes imaging the bonded portion of the wire structure; step (b) includes imaging a plurality of portions of the wire structure; further including a step of assembling a digital representation of the wire structure using results of step (b); step (b) includes imaging the free end of the wire structure and imaging the bonded portion of the wire structure; step (b) includes imaging at least one portion of the wire structure between (i) the bonded portion of the wire structure and (ii) the free end of the wire structure; the position of the portion of the wire structure is an x-y position; the position of the portion of the wire structure is a z-axis position; steps (a), (b), and (c) are repeated after step (d); the portion of the wire structure is the free end of the wire structure, and wherein an adjustment is made to at least one of a wire looping parameter and a wire bonding parameter in step (d) if it is determined that the position of the free end of the wire structure is not acceptable; the portion of the wire structure is the bonded portion of the wire structure, and wherein an adjustment is made to a wire bonding parameter in step (d) if it is determined that the position of the bonded portion of the wire structure is not acceptable; step (b) includes imaging the portion of the wire structure at a first focal plane of the wire bonding system, the first focal plane being coincident with an expected height of the portion of the wire structure; step (b) includes imaging the portion of the wire structure at a second focal plane of the wire bonding system if results of imaging of the portion are not acceptable at the first focal plane; step (a) includes forming a plurality of the wire structures at respective bonding locations of the workpiece, and step (b) includes imaging the portion of each of the plurality of the wire structures on the wire bonding system; further including a step of determining a height of the wire structure; the step of determining the height of the wire structure is determined using results of step (b); the step of determining the height of the wire structure is determined by contacting the free end of the wire structure using a free air ball positioned at an end of a wire bonding tool used to form the wire structure; step (b) includes performing the imaging using a camera positioned above the wire structure, the camera being carried by a bond head assembly of the wire bonding system; step (b) includes performing the imaging using a camera positioned above the wire structure and at least one optical element for imaging a side portion of the wire structure; and/or step (b) includes performing the imaging using a plurality of cameras on the wire bonding system.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIGS. 1A-1B are block diagram side views of a wire bonding system used in connection with various exemplary embodiments of the invention;

FIG. 2 is a table illustrating results of imaging operations of wire structures in accordance with various exemplary embodiments of the invention;

FIG. 3A is a block diagram side view illustrating imaging of a portion of a wire structure on a wire bonding system in accordance with an exemplary embodiment of the invention;

FIG. 3B is a top view of the results of the imaging operation of FIG. 3A;

FIG. 4A is a block diagram side view illustrating imaging of a portion of another wire structure on a wire bonding system in accordance with an exemplary embodiment of the invention;

FIG. 4B is a top view of the results of the imaging operation of FIG. 4A;

FIGS. 5A-5B are block diagram side views illustrating imaging operations on a wire bonding system with respect to yet another wire structure in accordance with an exemplary embodiment of the invention;

FIGS. 6A-6D are block diagram side views illustrating imaging operations on a wire bonding system with respect to yet another wire structure in accordance with an exemplary embodiment of the invention;

FIGS. 7A-7D are block diagram side views illustrating imaging operations on a wire bonding system with respect to yet another wire structure in accordance with an exemplary embodiment of the invention;

FIGS. 8A-8C are block diagram side views illustrating imaging operations on a wire bonding system with respect to a plurality of wire structures in accordance with an exemplary embodiment of the invention;

FIGS. 9A-9D are block diagram side, and top, views illustrating imaging operations on a wire bonding system with respect to yet another wire structure in accordance with an exemplary embodiment of the invention;

FIGS. 10A-10D are block diagram side views illustrating imaging operations on a wire bonding system with respect to yet another wire structure in accordance with an exemplary embodiment of the invention;

FIGS. 11A-11C are block diagram side views illustrating imaging, and wire bonding, operations on a wire bonding system with respect to yet another wire structure in accordance with an exemplary embodiment of the invention;

FIGS. 12A-12C are block diagram side views illustrating imaging, and wire bonding, operations on a wire bonding system with respect to yet another wire structure in accordance with an exemplary embodiment of the invention;

FIGS. 13A-13C are block diagram side views illustrating imaging, and height measurement, operations on a wire bonding system with respect to yet another wire structure in accordance with an exemplary embodiment of the invention;

FIGS. 14A-14B and FIGS. 15-16 are block diagram side views illustrating imaging operations on wire bonding systems with respect to wire structures in accordance with various exemplary embodiments of the invention; and

FIGS. 17-20 are flow diagrams illustrating methods of imaging wire structures on various wire bonding systems in accordance with various exemplary embodiments of the invention.

### DETAILED DESCRIPTION

Aspects of the invention are directed to methods of imaging a wire structure (e.g., a vertical wire structure) on a wire bonding system and related methods of operating the wire bonding system. Exemplary aspects of the invention are aimed at providing a consistent vertical height of a wire structure, and a consistent position of the wire structure (e.g., consistent position of the bonded portion of the wire structure, and consistent position of a wire tip/free end of the wire structure, consistent formation of the wire structure, consistent sway or lack thereof of the body portion/free end portion of the wire structure, etc.). Further, additional aspects of the invention are aimed at other defects (not just positional defects) such as wire defects (e.g., clamp marks on a wire) or other deformations.

Aspects of the invention use imaging techniques to: (i) check for the presence of a wire structure (e.g., a vertical wire structure); (ii) measure a height of the wire structure; (iii) determine a position of the bonded portion, body portion, and/or the free end of the wire structure; (iv) detect additional defects such as wire defects (e.g., clamp marks on a wire) or other deformations; and/or (v) adjust a wire bonding process (e.g., a bonding parameter) for future wire structures to be formed.

In accordance with various exemplary embodiments of the invention, after one or more wire structures are bonded to a workpiece, an imaging system (e.g., a top-down imaging system on a wire bonding system) captures one or more images of the wire structure(s). For example, an image may be captured with a focal plane at the desired height of the wire structure, and additional images may be captured at focal planes that differ from that of the desired height. The images at the different focal planes may be captured, for example, by moving one or more optical lenses using a stepper motor, a voice coil, and/or other mechanisms. Another exemplary way to capture images at different focal planes would be to change a height of the workpiece (e.g., by raising or lowering a portion of a support structure supporting the workpiece).

For each image captured (or multiple images, in cases where a single feature may be devised from multiple images), image features are calculated using image processing (e.g., traditional image processing, a convolutional neural network, machine learning, artificial intelligence, etc.). If multiple images at different focal planes were captured, the image features may be compared between focal planes and/or between the current sample(s) and known good sample(s), using mathematical, statistical, and/or machine learning methods to determine whether the wire structure (e.g., the wire tip/free end of the wire structure) is present (e.g., not missing and not broken) and within a desired height range.

If the wire tip (or other portion of the wire structure, such as the bonded portion) is detected to be within the desired height range, the image previously captured at the focal plane coincident with the wire tip (e.g., free end) may be used to locate the position of the wire tip in an x-y plane. Optionally, if the wire tip is not detected within the desired height range, additional images at varying focal planes are captured until a wire tip is detected, and the respective wire positions and heights are determined. This information may be used to correct the wire tip position of subsequent wire structures, such that the wire structures (e.g., the wire tips) are at the desired position and/or height.

Thus, aspects of certain embodiments of the invention may be: detecting the presence (or absence) of a wire tip of a wire structure within a desired height range; locating the x-y position of the wire tip; and/or correcting the position (e.g., the x-y position, the z position, the xyz position, a 3D position, a relative position, bend or sway of the body portion or free end, etc.) of subsequent wire structures using adjusted wire bonding and/or wire looping parameters.

Aspects of the invention relate to checking for the presence (or absence) of the wire tip at a desired height before determining its x-y position, without the necessity of making a 3D reconstruction of the wire structure from multiple focal plane images, and automatically correcting for unacceptable positions of the wire structure (e.g., the position of the wire tip, the position of the bonded portion, etc.) using the results from the vision system.

As used herein, the term “wire structure” is intended to refer to a length of wire including (i) a bonded portion bonded to a bonding location of a workpiece on a wire bonding system, and (ii) a free end (e.g., a wire tip) continuous with the bonded portion. Exemplary wire structures may be considered vertical wire structures-but not all wire structures are vertical. Exemplary wire structures may be used as: (i) conductive interconnects; (ii) shielding structures; etc. Exemplary wire structures are sometimes described in the art as “vertical wires” and/or “pin wires”. In certain contexts used herein, “wire tip”, “free end”, and “end portion” may be used interchangeably. Of course, aspects of the invention may apply to other types of wire structures (e.g., wire loops with both a first bond and a second bond, conductive bumps, etc.).

As used herein, the term “workpiece” is intended to refer to any element or structure configured to receive a wire structure on a wire bonding system. Exemplary workpieces include semiconductor die, semiconductor wafers, substrates, etc. Exemplary bonding locations of the workpiece include bond pads, conductive leads, conductive traces, other portions of wire, amongst others.

It should be understood that like reference numerals refer to like elements throughout the various drawings, unless indicated otherwise.

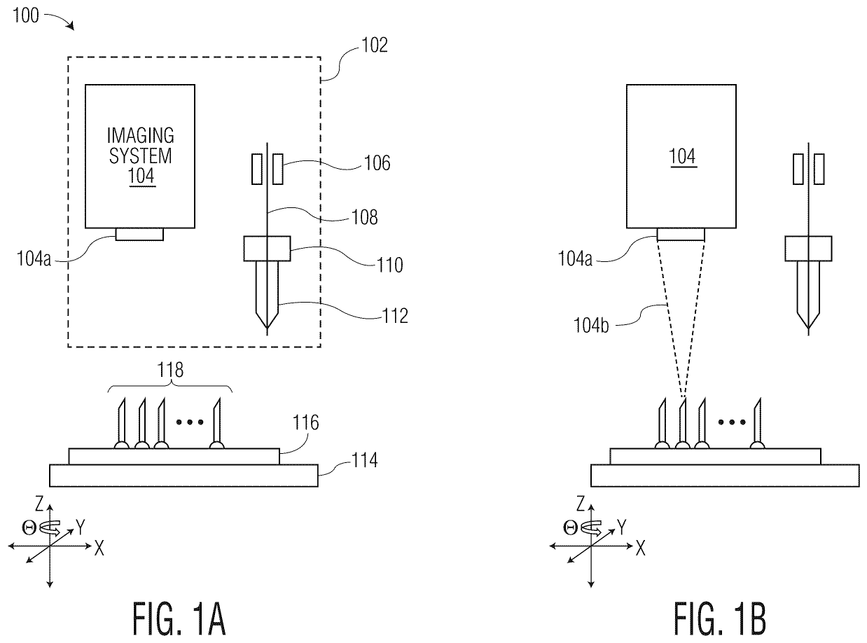

FIG. 1A illustrates a wire bonding system 100 which includes a bond head assembly 102 and a support structure 114. Bond head assembly 102 includes an imaging system 104 (including an objective lens 104a), a wire clamp 106, an ultrasonic transducer 110, and a wire bonding tool 112 (e.g., a capillary wire bonding tool, a wedge bonding tool, etc.). A wire 108 (provided by a wire supply, such as a spool of wire) passes through wire clamp 106, and through wire bonding tool 112. Using wire 108, wire bonding tool 112 forms wire structures 118 on a workpiece 116. Workpiece 116 is illustrated supported by support structure 114 (e.g., a heat block, an anvil, etc.). As illustrated in FIG. 1A, a plurality of wire structures 118 have been bonded to bonding locations on workpiece 116. Of course, many additional (or different) elements that may be included in wire bonding system 100 are not shown for simplicity (e.g., motion systems, material handling systems, wire cutters, etc.).

In accordance with aspects of the invention, portions of wire structures 118 may be imaged using imaging system 104. FIG. 1B illustrates imaging system 104 imaging an end portion (e.g., a free end) of one of the plurality of wire structures 118. More specifically, light 104b is reflected from the end portion of the wire structure 118, and is received by an objective lens 104a. By receiving light 104b, an image of the end portion of the wire structure 118 is received, and may be processed on wire bonding system 100 (e.g., using a computer and/or image processing software of wire bonding system 100).

Different portions of a wire structure may be imaged depending upon the focal plane utilized during imaging operations. For example, a wire structure includes (i) a bonded portion bonded to a bonding location of a workpiece (e.g., a bond pad of the workpiece), (ii) a free end, and (iii) a body portion (a length of wire) between the bonded portion and the free end. An imaging system could focus an imaging operation on a desired portion(s) of the wire structure. For example, the imaging system may be configured with a focal plane (with a corresponding depth of field) configured to image the free end (e.g., the wire tip) of the wire structure.

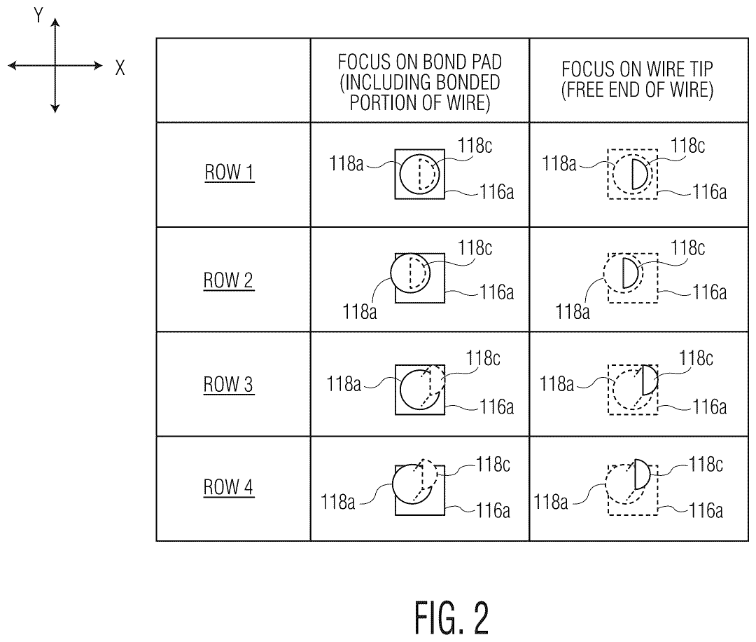

FIG. 2 is a table illustrating examples of different portions of a wire structure to be imaged, and information regarding the resultant images. The center column of FIG. 2 illustrates images focused on the bonded portion of the wire structure (and/or the bond pad to which the bonded portion is bonded). As shown in this center column, a bonded portion 118a of the wire structure and a bond pad 116a of the workpiece are shown in solid lines (indicating bonded portion 118a and bond pad 116a are in the focal plane and/or associated depth of field) (it being understood that in certain embodiments of the invention, only one of the bonded portion 118a and the bond pad 116a would be in the focal plane), while a free end 118c of the wire structure (which is not in the focal plane and/or associated depth of field) is shown in dotted lines. The right-hand column of FIG. 2 illustrates images focused on the wire tip of the wire structure (i.e., the free end of the wire structure). As shown in this right-hand column, the free end 118c of the wire structure is shown in solid lines, while the bonded portion 118a of the wire structure (and the bond pad 116a of the workpiece), are shown in dotted lines. “ROW 1” of FIG. 2 illustrates a straight wire structure (e.g., vertical wire), with a bonded portion 118a aligned well with respect to bond pad 116a. “ROW 2” of FIG. 2 illustrates a straight wire structure, but with a bonded portion 118a that is poorly aligned with respect to bond pad 116a. “ROW 3” of FIG. 2 illustrates a tilted wire structure, with a bonded portion 118a aligned well with respect to bond pad 116a. “ROW 4” of FIG. 2 illustrates a tilted wire structure, with a bonded portion 118a that is poorly aligned with respect to bond pad 116a. Despite the examples shown in FIG. 2 (and described herein), it is contemplated that a depth of field may be large enough to capture an entire wire structure in focus.

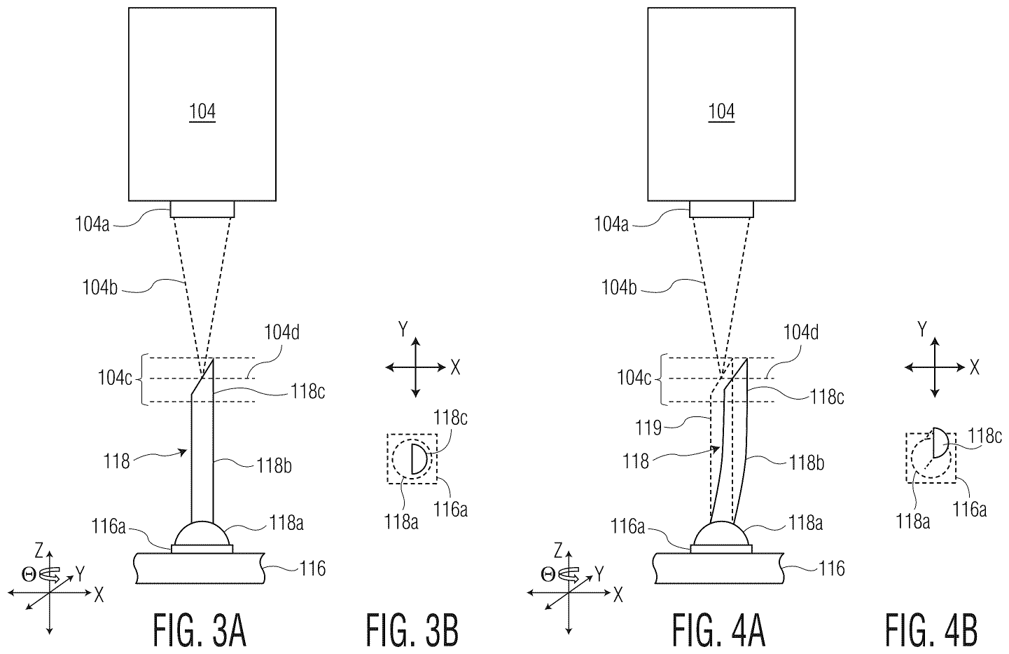

FIGS. 3A-3B, FIGS. 4A-4B, FIGS. 5A-5B, FIGS. 6A-6D, FIGS. 7A-7D, FIGS. 8A-8C, FIGS. 9A-9D, FIGS. 10A-10D, FIGS. 11A-11C, FIGS. 12A-12C, FIGS. 13A-13C, FIGS. 14A-14B, FIG. 15, and FIG. 16, illustrate imaging operations on wire bonding systems (such as wire bonding system 100 shown in FIG. 1A) with various elements removed for simplicity. Nonetheless, it is understood that these imaging operations are performed on wire bonding systems, such as wire bonding system 100 shown in FIG. 1A.

Referring specifically to FIG. 3A, a wire structure 118 has been bonded to a bond pad 116a of a workpiece 116. Wire structure 118 includes a bonded portion 118a (e.g., a bonded free air ball), a free end 118c (e.g., a wire tip of wire structure 118), and a body portion 118b (i.e., a length of wire between bonded portion 118a and free end 118c). Wire structure 118 is a continuous length of wire including bonded portion 118a, free end 118c, and body portion 118b between bonded portion 118a and free end 118c.

Imaging system 104 is illustrated imaging a portion of a wire structure 118. More specifically, light 104b (provided by imaging system 104) is reflected from free end 118c of wire structure 118 and is received by objective lens 104a of imaging system 104. Imaging system 104 may produce an image of free end 118c from received light 104b. Free end 118c is imaged at a focal plane 104d (having a depth of field 104c). The image is processed using image processing techniques to determine if the position of free end 118c is acceptable. As illustrated in the image of FIG. 3B, free end 118c is clearly imaged in depth of field 104c (as indicated by the solid lines). According to criteria considered in the image processing operation, free end 118c is considered to be in a desirable/acceptable position (e.g., an x-y position, a z position, an xyz position also known as a 3D position in space, etc.). Focal plane 104d may be selected based on an expected height (e.g., a z position), and/or an expected x-y position, of free end 118c. It may also be considered that the field of view (including the focal plane) is selected on an expected x-y position of free end 118c. In FIG. 3B, since a clear image is produced at focal plane 104d, the z position of the free end (e.g., wire tip) may be deemed acceptable. It should be understood that the meaning of the term “acceptable” can vary, and such term is not limited to cases where the free end/wire tip is clearly imaged at a given focal plane.

Referring now to FIGS. 4A-4B, a free end 118c of a wire structure 118 is again imaged; however, the x-y position of free end 118c is not in a desired/acceptable x-y position (e.g., as determined using criteria considered in the image processing operation). For example, wire structure 118 in FIGS. 4A-4B is tilted, such that free end 118c is not in a desired/acceptable x-y position. Referring specifically to FIG. 4A, wire structure 118 (e.g., an “as-formed” wire structure) is illustrated in solid lines, whereas an expected wire structure 119 (e.g., an acceptable, desirable or ideal wire structure) is illustrated in dashed lines. Referring specifically to FIG. 4B, free end 118c is a feature in focus (e.g., at the focal plane, within an associated depth of field, etc.) and is illustrated in solid lines, whereas a bond pad 116a and a bonded portion 118a are out of focus and are illustrated in dashed lines.

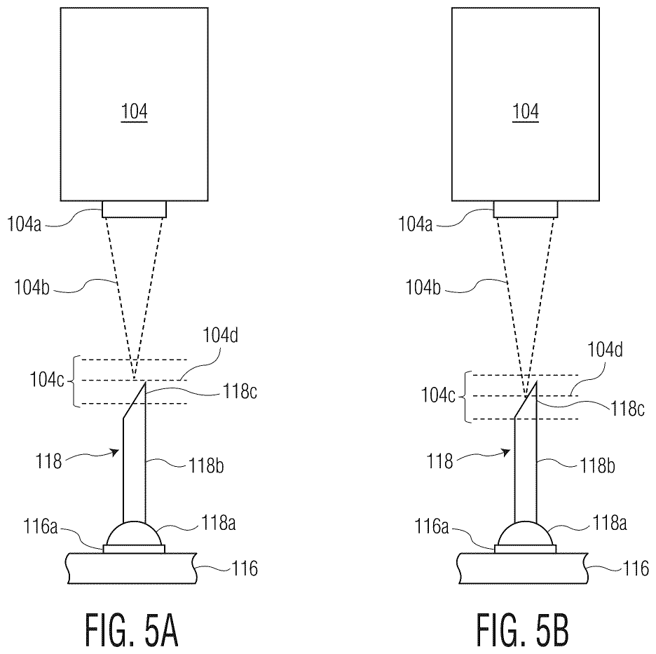

Referring now to FIG. 5A, a free end 118c of a wire structure 118 is imaged. While free end 118c is found in the depth of field 104c, the confidence of the z position of free end 118c is low because of the height of wire structure 118 (e.g., the height of wire structure 118 is lower than expected). In FIG. 5B, the imaging operation is repeated, with free end 118c imaged at a second (lower) focal plane 104d (having a lower depth of field 104c). Because the second (lower) focal plane is coincident with free end 118c, the confidence that the z position of free end 118c has been located is higher. By imaging with a plurality of distinct focal planes, a position (e.g., height, a z position, etc.) of free end 118c can be determined (e.g., to be acceptable).

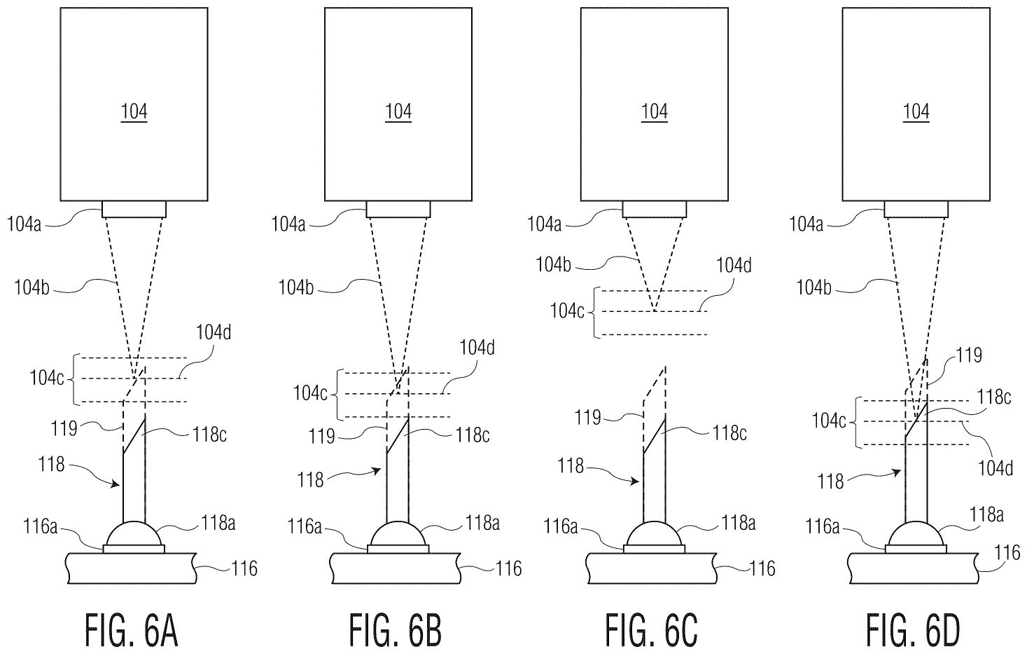

Referring now to FIG. 6A, a free end 118c of a wire structure 118 is imaged; in this case, the height of wire structure 118 is much lower (i.e., the expected height of expected wire structure 119 is shown in FIGS. 6A-6D in dotted lines, while the actual “as formed” wire structure 118 is shown in solid lines). Therefore, in FIG. 6A, free end 118c is not found in depth of field 104c. At FIG. 6B, the imaging operation is repeated, at a second (lower) focal plane 104d (having a lower depth of field 104c). However, free end 118c is still not found in depth of field 104c. At FIG. 6C, the imaging operation is repeated, at a third (higher) focal plane 104d (having a higher depth of field 104c). However, free end 118c is still not found in depth of field 104c. At FIG. 6D, the imaging operation is repeated, at a fourth (still lower) focal plane 104d (having a still lower depth of field 104c). However, in this case, free end 118c is found because it is in depth of field 104c. Thus, through this iterative process (changing the focal plane to image at a plurality of distinct focal planes, and the associated depth of field), the confidence that free end 118c has now been located in FIG. 6D is high, where the height of wire structure 118 can be determined. It should be understood that this iterative process may occur automatically (or manually), and may be adjusted based on prior learning (e.g., varying the approach of changing the focal plane, etc.).

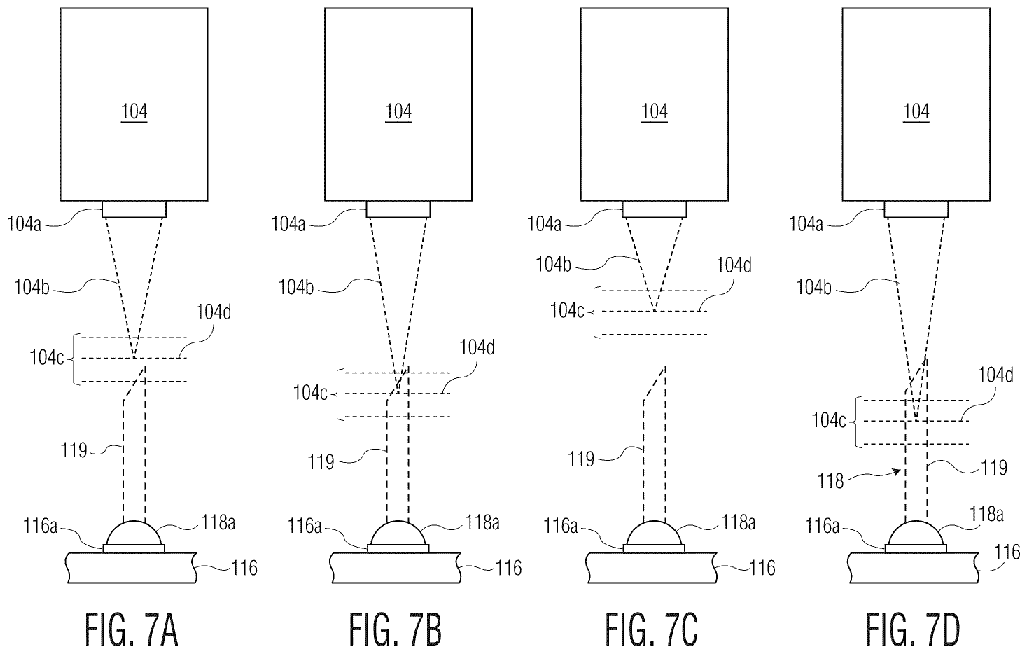

Referring now to FIG. 7A, a wire structure was not properly formed. That is, after formation of a bonded portion 118a, the wire was broken such that the remainder of the wire structure (e.g., the body portion and the free end portion, whose positions are shown in dotted lines in FIGS. 7A-7D as expected wire structure 119) is missing from bonded portion 118a. Therefore, in FIG. 7A, the wire tip is not found at focal plane 104d/in depth of field 104c. At FIG. 7B, the imaging operation is repeated, at a second (lower) focal plane 104d (having a lower depth of field 104c); however, the wire tip is still not found at focal plane 104d/in depth of field 104c. At FIG. 7C, the imaging operation is repeated, at a third (higher) focal plane 104d (having a higher depth of field 104c); however, the wire tip is still not found at focal plane 104d/in depth of field 104c. At FIG. 7D, the imaging operation is repeated, at a fourth (still lower) focal plane 104d (having a still lower depth of field 104c); however, in this case, the free end (wire tip) is still not found at focal plane 104d/in depth of field 104c. Thus, through this iterative process (changing the focal plane to image at a plurality of distinct focal planes, and the associated depth of field), because the free end (wire tip) is not found, it is determined that the wire structure is not properly formed and/or is missing. Thus, aspects of the invention may be utilized to detect the presence (or absence) of a wire structure.

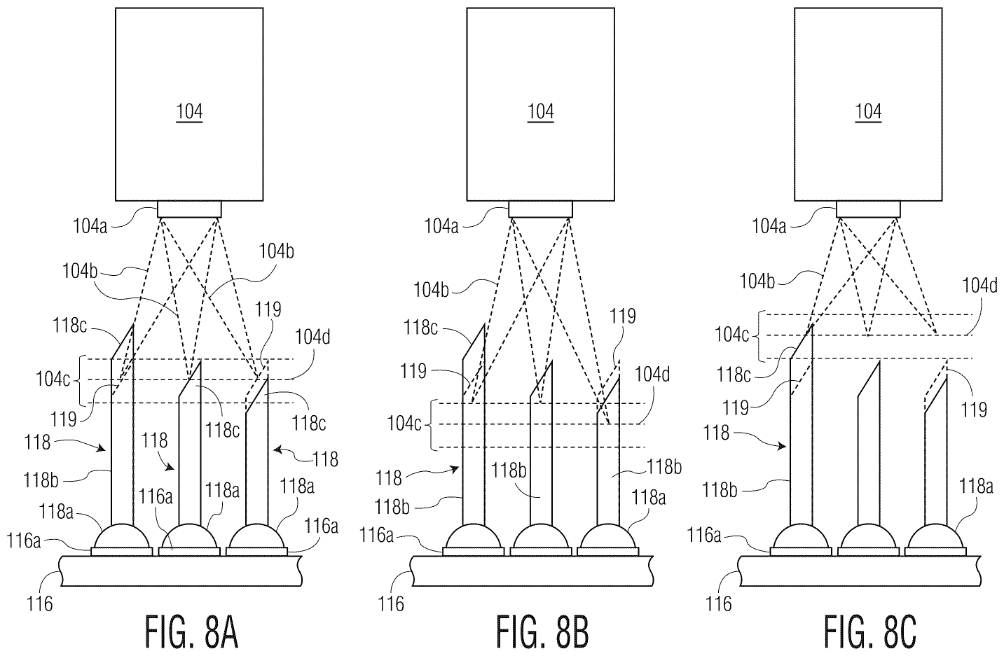

Although FIGS. 3A-3B, FIGS. 4A-4B, FIGS. 5A-5B, FIGS. 6A-6D, and FIGS. 7A-7D relate to imaging a single wire structure (one at a time), the invention is not limited thereto. More specifically, portions of a plurality of wire structures may be imaged on a wire bonding system simultaneously. FIGS. 8A-8C illustrate an example of such an embodiment. Prior to imaging in FIG. 8A, a plurality of wire structures 118 have been formed. As shown in FIG. 8A: the leftmost wire structure 118 is taller than expected (where the expected shape and position are shown in dotted lines as expected wire structure 119); the center wire structure 118 has a height as expected; and the rightmost wire structure 118 is shorter than expected (where the expected shape is provided in dotted lines as expected wire structure 119). During the imaging operation in FIG. 8A, light 104b is reflected from each of the wire structures and is received by objective lens 104a of imaging system 104 (e.g., for image processing). In FIG. 8A: for the leftmost wire structure 118, free end 118c is not found at focal plane 104d/in depth of field 104a; for the centrally located wire structure 118, free end 118c of wire structure 118 is found at focal plane 104d/in depth of field 104a; and for the rightmost wire structure 118, free end 118c is found at focal plane 104d/in depth of field 104c (albeit at a lower confidence). Thus, additional imaging operations (e.g., at different and distinct focal planes) may be performed to find free end 118c of the leftmost wire structure 118.

In FIG. 8B, the imaging operation is repeated, at a second (lower) focal plane 104d (having a lower depth of field 104c); however, free end 118c of the leftmost wire structure 118 is still not found at focal plane 104d/in depth of field 104c. At FIG. 8C, the imaging operation is repeated, at a third (higher) focal plane 104d (having a higher depth of field 104c); however, free end 118c of the leftmost wire structure 118 is found because free end 118c is at focal plane 104d/in depth of field 104c. Thus, through this iterative process (changing the focal plane to image at a plurality of distinct focal planes, and the associated depth of field), the confidence that free end 118c of each of the wire structures 118 has now been located is high.

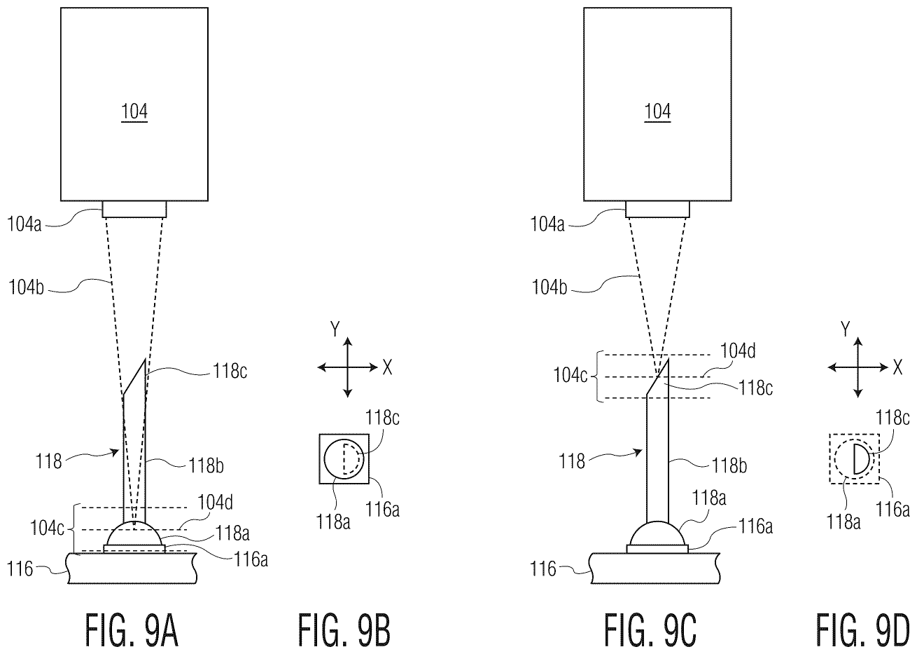

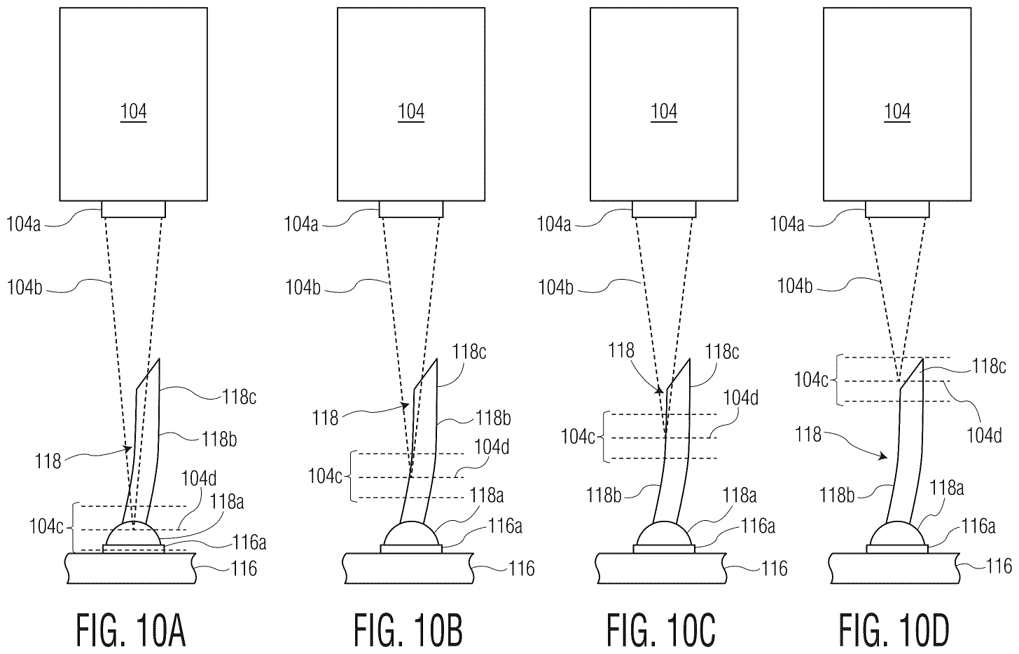

In accordance with various aspects of the invention, imaging of a plurality of portions of a wire structure may be completed. For example, both (i) a free end of a wire structure (e.g., the wire tip) and (ii) a bonded portion of the wire structure may be imaged. Further, one or more portions of the wire structure between the free end and the bonded portion may be imaged. Using the imaged portions of the wire structure, a digital representation of the wire structure may be assembled (e.g., a 2D representation, a 3D representation, etc.). Further, determinations as to whether a position of the different imaged portions of the wire structure is acceptable can be made (e.g., if the x-y position of the imaged portion is acceptable, if the z position of the imaged portion is acceptable, if the xyz position in space is acceptable, if the position of one portion of the wire structure relative to another portion is acceptable, etc.). FIGS. 9A-9D and FIGS. 10A-10D are examples where a plurality of portions of a wire structure are imaged (e.g., using a plurality of distinct focal planes).

Referring specifically to FIG. 9A, a bonded portion 118a of a wire structure 118 is imaged at a first focal plane 104d (having a depth of field 104c), where FIG. 9B is a top-down view illustrating bond pad 116a and bonded portion 118a being clearly imaged at the first focal plane 104d (bond pad 116a and bonded portion 118a are shown in solid lines in FIG. 9B). At FIG. 9C, a free end 118c of wire structure 118 is imaged at a second focal plane 104d (having a depth of field 104c), where FIG. 9D is a top-down view illustrating free end 118c being clearly imaged at the second focal plane 104d (free end 118c is shown in solid lines in FIG. 9D). Thus, through these two imaging operations, two different portions of wire structure 118 (i.e., bonded portion 118a and free end 118c) are imaged at two different focal planes 104d. Using information from these different imaging operations, it can be determined if the positions of the imaged portions of wire structure 118 (i.e., bonded portion 118a and free end 118c) are acceptable according to predetermined position criteria (e.g., within an acceptable x-y location range, within an acceptable z position range, within an acceptable 3D position range, within an acceptable bend condition and/or a sway condition of the wire structure, a relative position of one portion of the wire structure relative to another portion is acceptable, etc.).

Referring now to FIG. 10A, a bonded portion 118a of a wire structure 118 is imaged at a first focal plane 104d (having a depth of field 104c). At FIG. 10B, another portion of wire structure 118 (part of body portion 118b, above bonded portion 118a) is imaged at a second focal plane 104d (having depth of field 104c). At FIG. 10C, yet another portion of wire structure 118 (another part of body portion 118b, further above bonded portion 118a) is imaged at a third focal plane 104d (having depth of field 104c). At FIG. 10D, a free end 118c is imaged at a fourth focal plane 104d (having depth of field 104c). Thus, through these multiple imaging operations, different portions of wire structure 118 are imaged at a plurality of distinct focal planes 104d. In some embodiments, a digital representation of the wire structure may be assembled using the imaged portions of wire structure 118.

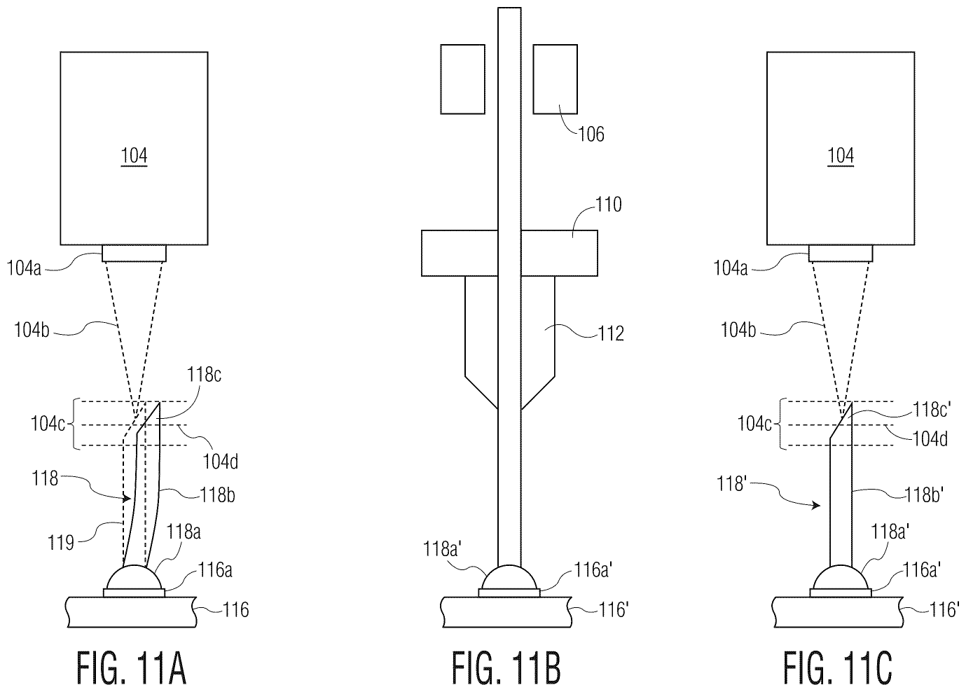

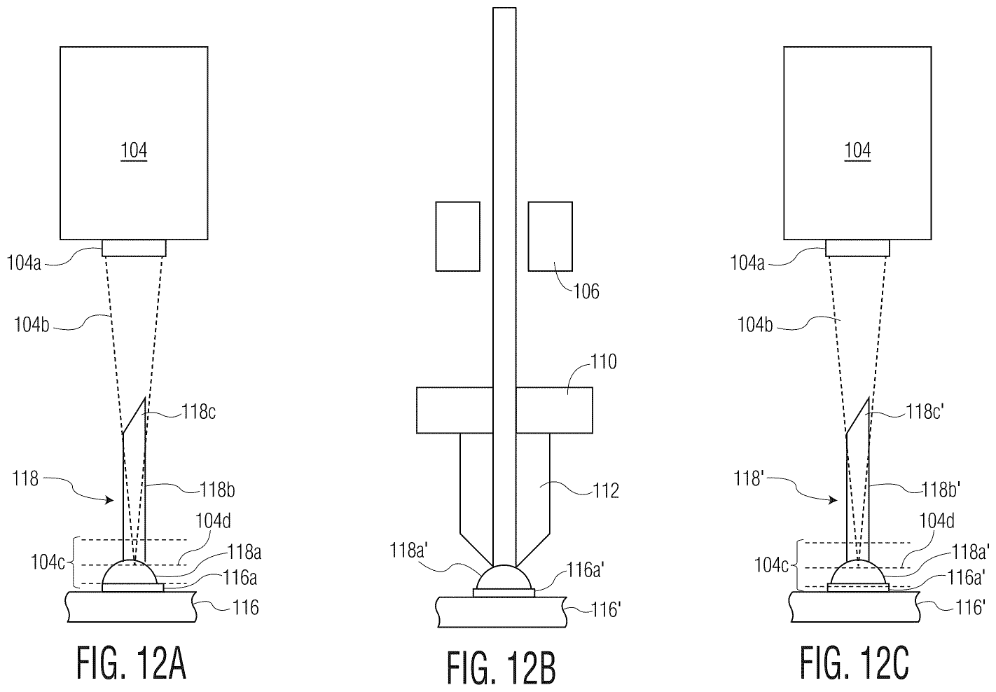

Using the results of the various imaging operations disclosed herein, improvements in wire bonding operations may be made. For example, after imaging a portion of a wire structure, it may be determined that the position (e.g., an x-y position, a z position, a 3D position in space, a relative position of one portion of the wire structure relative to another portion is acceptable, a bend/sway of the wire structure, etc.) of the imaged portion is unacceptable (e.g., according to predetermined criteria, such as an acceptable positional range, etc.). Using this knowledge (of an unacceptable position of a portion of the wire structure), changes can be made in future wire bonding operations to address the unacceptable position. For example, if the x-y position of the bonded portion of a wire structure is unacceptable, wire bonding parameters (e.g., a position of the bonded portion, the size of the free air ball used to form the bonded portion, bond force applied during formation of the bonded portion, ultrasonic energy applied during formation of the bonded portion, etc.) may be adjusted when forming bonded portions of future wire structures. For example, if the xyz position of the wire tip (e.g., the free end) of a wire structure is unacceptable, looping parameters (e.g., the motion profile of a wire bonding tool during formation of the wire structure, etc.) may be adjusted when forming future wire structures. Further, the wire bonding system may automatically calculate the adjustment to the parameters (e.g., the wire bonding parameters and/or the wire looping parameters) to achieve an acceptable position for the imaged portion of the wire structure. FIGS. 11A-11C and FIGS. 12A-12C are examples illustrating adjustments made in connection with the formation of wire structures based on an unacceptable initial wire structure.

Referring specifically to FIG. 11A, a free end 118c of a wire structure 118 (bonded to a workpiece 116) is imaged at a first focal plane 104d (having a depth of field 104c). Through image processing, it is determined that the x-y position of free end 118c is offset from a desired position, and the x-y position is therefore unacceptable. FIG. 11B illustrates the process of forming another wire structure (i.e., a wire structure 118′ of FIG. 11C) on bond pad 116a′ of another workpiece 116′, using wire bonding tool 112 (see FIGS. 1A-1B and the associated description). Wire structure 118′, including a bonded portion 118a′, a free end 118c′, and a body portion 118b′, is formed with at least one adjusted wire looping and/or bonding parameter (e.g., the motion profile of wire bonding tool 112 during formation of wire structure 118′, the deformation or partial cutting of an end of the wire during formation of the wire structure, etc.). FIG. 11C illustrates imaging of free end 118c′ of wire structure 118′ (illustrated being formed at FIG. 11B, with the adjusted wire looping parameter(s)) at first focal plane 104d. Through image processing of the image taken at FIG. 11C, it can be determined that free end 118c′ is located at an acceptable position. That is, the adjusted wire looping and/or bonding parameter(s) has resulted in a wire structure 118′ with a free end 118c′ having an acceptable position. Of course, this process of adjusting a wire looping and/or bonding parameter(s) may be repeated until an acceptable position of free end 118c′ is imaged.

Referring now to FIG. 12A, a bonded portion 118a of a wire structure 118 (bonded to a workpiece 116) is imaged at a first focal plane 104d (having a depth of field 104c). Through image processing, it is determined that the x-y position of bonded portion 118a is offset from a desired position (e.g., bonded portion 118a is not properly centered on bond pad 116a of workpiece 116), and the x-y position of bonded portion 118a is therefore unacceptable. FIG. 12B illustrates the process of forming another wire structure (wire structure 118′ of FIG. 12C, including a free end 118c′, a bonded portion 118a′, and a body portion 118b′) on another bond pad 116a′ of another workpiece 116′ using wire bonding tool 112. Wire structure 118′ is formed with at least one adjusted wire bonding parameter during formation of bonded portion 118a′ (e.g., a position of the bonded portion, the size of a free air ball used to form the bonded portion, bond force applied during formation of the bonded portion, ultrasonic energy applied during formation of the bonded portion, etc.). FIG. 12C illustrates imaging of bonded portion 118a′ of wire structure 118′ (illustrated being formed at FIG. 12B, with the adjusted wire bonding parameter(s)) at first focal plane 104d. Through image processing of the image taken at FIG. 12C, bonded portion 118a′ is determined to be located at an acceptable position. That is, the adjusted wire bonding parameter(s) has resulted in a wire structure 118′ with a bonded portion 118a′ having an acceptable position (e.g., properly positioned with respect to bond pad 116a′). Of course, this process of adjusting a wire bonding parameter(s) may be repeated until an acceptable position of bonded portion 118a′ is achieved.

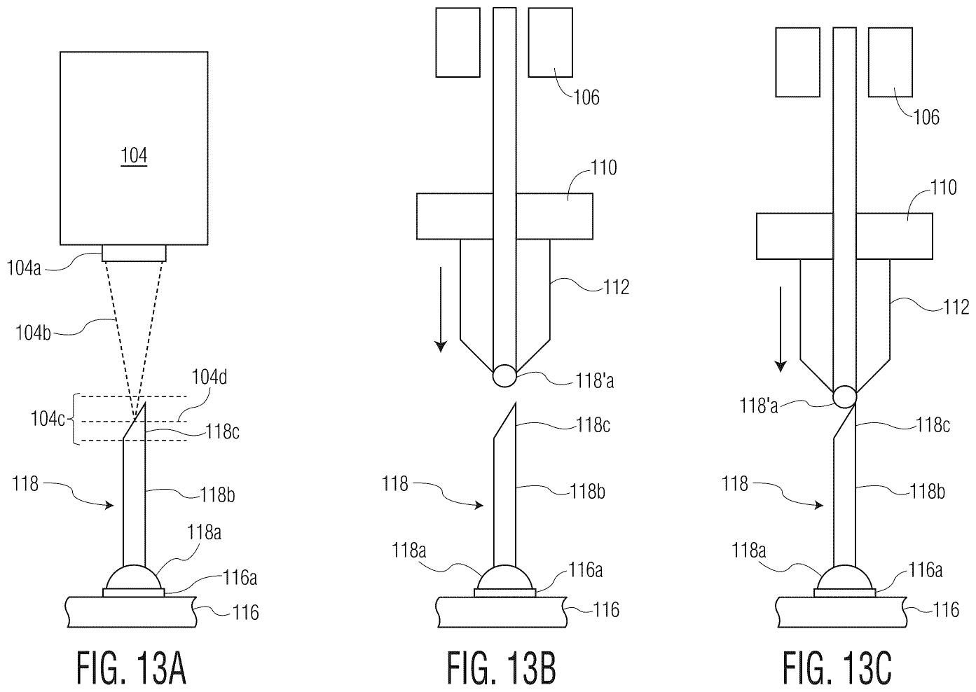

Aspects of the invention relate to determining a height of a wire structure. Various methods may be used to determine the height. For example, the imaging operations described herein may be used to determine the height (e.g., by determining a height of a focal plane useful to image the free end/wire tip of a wire structure). In another example, after finding a position of a wire tip of a wire structure (e.g., using the imaging described herein), the height of the wire structure may be determined by contacting the wire tip (e.g., the free end) of the wire structure using a free air ball positioned at an end of the wire bonding tool used to form the wire structure such as disclosed at PCT International Publication Number WO 2009/002345. FIGS. 13A-13C illustrate such a process.

Referring specifically to FIG. 13A, free end 118c of wire structure 118 is imaged at a focal plane 104d (having a depth of field 104c). The image is processed using image processing techniques to determine the position of free end 118c. At FIG. 13B, a free air ball 118′a positioned at the end of wire bonding tool 112 is being moved toward free end 118c of wire structure 118 (e.g., through motion of wire bonding tool 112). At FIG. 13C, free air ball 118′a contacts free end 118c of wire structure 118, where the height of this contact is determined, thereby enabling detection of the height of wire structure 118. Details of using such a free air ball to contact a wire loop are disclosed in PCT International Publication Number WO 2009/002345 (“METHOD OF DETERMINING A HEIGHT PROFILE OF A WIRE LOOP ON A WIRE BONDING MACHINE”), which is incorporated by reference in its entirety.

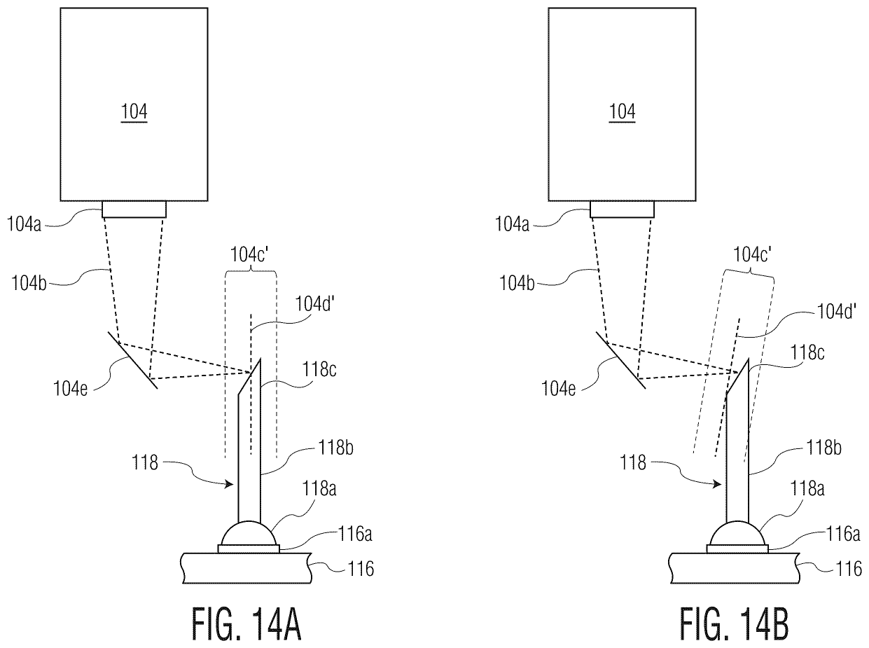

Although the invention has been described primarily with respect to imaging from a position above a wire structure (thereby providing an image from above the wire structure), it is not limited thereto. FIGS. 14A-14B illustrate exemplary uses of an imaging system 104 (e.g., including a camera) carried by a bond head assembly (see bond head assembly 102 from FIG. 1A) of a wire bonding system, where an additional optical element 104e (e.g., a mirror, a prism, a lens, etc.) is used in connection with the camera of imaging system 104 to image a side portion of wire structure 118. In FIG. 14A, the imaging path is a sideways path aimed directly at a portion of wire structure 118, providing a horizontal depth of field 104c′ and a horizontal focal plane 104d′. In FIG. 14B, the positioning of optical element 104e is such that the imaging path is on a slight angle (providing an angled depth of field 104c) such that the imaging of the side portion of wire structure 118 is accomplished from above, irrespective of neighboring wire structures 118 (not shown) bonded to workpiece 116. Optical element 104e may be carried by the bond head assembly (see FIG. 1A). While a single additional optical element 104e is illustrated in FIGS. 14A-14B, it is understood that multiple optical elements may be utilized.

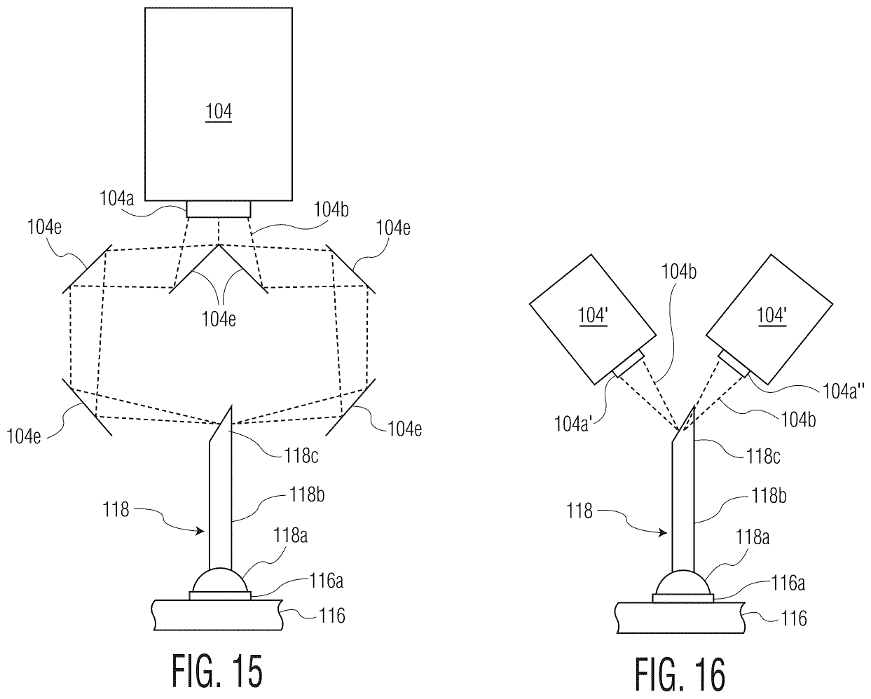

FIG. 15 illustrates an exemplary configuration (including multiple optical elements 104e) for imaging a free end 118c of wire structure 118 (or another portion of wire structure 118), with multiple imaging paths, capturing different views of free end 118c.

FIG. 16 illustrates an exemplary configuration for imaging a free end 118c of wire structure 118 (or another portion of wire structure 118), using a plurality of cameras 104′ (and associated objective lenses 104a′, 104a″), thereby capturing different views of free end 118c (or another portion of wire structure 118).

It should be understood that the teachings of FIGS. 1A-1B, FIG. 2, FIGS. 3A-3B, FIGS. 4A-4B, FIGS. 5A-5B, FIGS. 6A-6D, FIGS. 7A-7D, FIGS. 8A-8C, FIGS. 9A-9D, FIGS. 10A-10D, FIGS. 11A-11C, FIGS. 12A-12C, FIGS. 13A-13C (e.g., imaging using a plurality of distinct focal planes, imaging a plurality of wire structures simultaneously, determining a height of the wire structure using image processing, adjusting wire bonding parameters or wire looping parameters if it is determined that the position of the portion of the wire structure is not acceptable, etc.) are applicable to FIG. 14, FIG. 15, and FIG. 16, and vice versa.

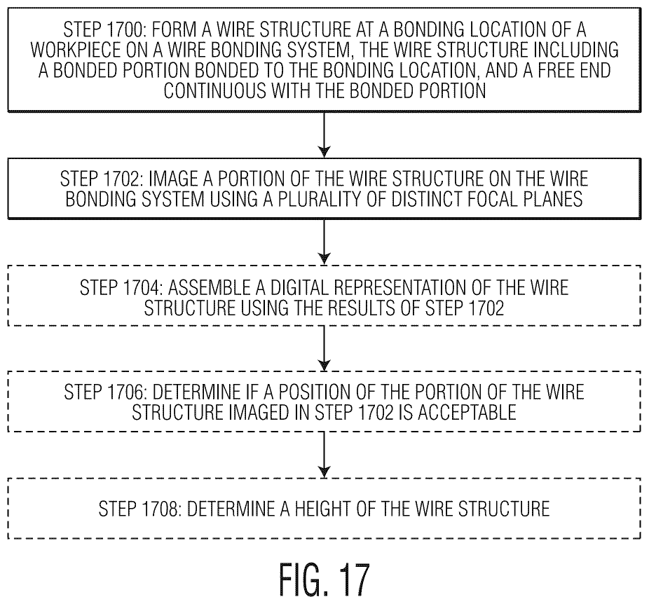

FIGS. 17-20 are flow diagrams illustrating methods of imaging wire structures on a wire bonding system. As is understood by those skilled in the art, certain steps included in the flow diagram may be omitted; certain additional steps may be added; and the order of the steps may be altered from the order illustrated-all within the scope of the invention.

Referring now to FIG. 17, at Step 1700, a wire structure is formed at a bonding location of a workpiece on a wire bonding system (e.g., wire bonding system 100 in FIG. 1A). The wire structure includes a bonded portion bonded to the bonding location, and a free end continuous with the bonded portion (e.g., see wire structures 118/118′, workpiece 116/116′, bonded portion 118a/118a′, and free end 118c/free end 118c′ in FIGS. 1A-1B, FIG. 3A, FIG. 4A, FIGS. 5A-5B, FIGS. 6A-6D, FIGS. 8A-8C, FIG. 9A, FIG. 9C, FIGS. 10A-10D, FIG. 11A, FIG. 11C, FIG. 12A, FIG. 12C, FIGS. 13A-13C, FIGS. 14A-14B, FIG. 15, and/or FIG. 16). At Step 1702, a portion of the wire structure on the wire bonding system is imaged using a plurality of distinct focal planes (e.g., see imaging of FIGS. 5A-5B, FIGS. 6A-6D, FIGS. 7A-7D, FIGS. 8A-8C, FIGS. 9A-9D, FIGS. 10A-10D, FIG. 11A, FIG. 11C, FIG. 12A, FIG. 12C, FIG. 13A, FIGS. 14A-14B, FIG. 15, and/or FIG. 16).

In certain embodiments, Step 1702 includes performing the imaging using a camera (e.g., of imaging system 104) positioned above the wire structure. In certain of such embodiments, the camera is carried by a bond head assembly (e.g., bond head assembly 102 of FIG. 1A) of the wire bonding system. In certain embodiments, Step 1702 includes using the camera (e.g., positioned above the wire structure) and at least one optical element for imaging a side portion of the wire structure (e.g., see FIGS. 14A-14B, FIG. 15, FIG. 16, etc.). In certain embodiments, Step 1702 includes performing the imaging using a plurality of cameras on the wire bonding system (e.g., see FIG. 16).

In certain embodiments, Step 1702 includes imaging the free end of the wire structure, imaging the bonded portion of the wire structure, and/or imaging a portion(s) of the wire structure between the free end and the bonded portion. In such embodiments, each portion being imaged may be imaged at/with a subset of the plurality of distinct focal planes. As used herein, “subset” is understood to include one or more of the plurality of distinct focal planes. In certain embodiments, Step 1702 includes imaging a plurality of portions of the wire structure (e.g., FIGS. 9A-9D and FIGS. 10A-10D). In certain embodiments, the method may further include imaging the free end of the wire structure and imaging the bonded portion of the wire structure (e.g., FIGS. 9A-9D). In certain embodiments, the method may further include the step of imaging at least one portion of the wire structure between (i) the bonded portion of the wire structure and (ii) the free end of the wire structure (e.g., FIGS. 10A-10D). In certain embodiments, Step 1702 may include imaging a plurality of portions of the wire structure, each of the plurality of portions being imaged at a subset of the plurality of distinct focal planes.

In certain embodiments, at optional Step 1704, a digital representation (e.g., a 2D representation, a 3D representation, etc.) of the wire structure is assembled using the results of Step 1702 (e.g., using the images of the plurality of portions of the wire structure).

At optional Step 1706, a position of a portion of the wire structure imaged in Step 1702 is determined to be acceptable (or not acceptable) (e.g., FIGS. 3A-3B, FIGS. 4A-4B, FIGS. 9A-9D, FIGS. 10A-10D, FIG. 11A, FIG. 12A, etc.). In certain embodiments, the position of the portion of the wire structure is a position in a horizontal plane of the wire bonding system (e.g., an x-y position of the portion of the wire structure). In certain embodiments, the position of the portion of the wire structure is a z-axis position (e.g., a height value) of the wire structure. In certain embodiments, the position of the portion of the wire structure is a 3D (xyz) position of the wire structure. In certain embodiments, an adjustment is made to at least one of (i) a wire bonding parameter and (ii) a wire looping parameter, if it is determined that the position of the portion of the wire structure is not acceptable (e.g., see FIGS. 11A-11C, 12A-12C, etc.). In such embodiments, Step 1700, Step 1702 (and associated Step 1704, if desired), and Step 1706 may be repeated after the adjustment is made.

In certain embodiments, the imaged portion of the wire structure is the free end of the wire structure, and wherein an adjustment is made to a wire looping and/or bonding parameter if it is determined that the position of the free end of the wire structure is not acceptable (FIGS. 11A-11C).

In certain embodiments, the imaged portion of the wire structure is the bonded portion of the wire structure, and wherein an adjustment is made to a wire bonding parameter if it is determined that the position of the bonded portion of the wire structure is not acceptable (e.g., FIGS. 12A-12C).

In certain embodiments, Step 1702 includes imaging a portion of the wire structure at a first focal plane of an imaging system of the wire bonding system (e.g., see FIG. 1B, FIG. 2, FIGS. 3A-3B, FIGS. 4A-4B, FIG. 5A, FIG. 8A, FIGS. 9A-9B, FIG. 10A, FIG. 11A, FIG. 12A, FIG. 12C, FIG. 13A, FIG. 14A, FIG. 15, FIG. 16, etc.). In certain of such embodiments, the first focal plane is coincident with an expected height of the portion of the wire structure (e.g., see FIGS. 3A-3B). In certain embodiments, Step 1702 includes imaging the portion of the wire structure at a second focal plane of an imaging system of the wire bonding system if the imaging of the portion is not acceptable at the first focal plane (e.g., see FIG. 5B, FIGS. 6B-6D, FIGS. 7B-7D, FIGS. 8B-8C, etc.). Step 1702 may also include imaging the portion of wire at additional focal planes of the imaging system (e.g., a third focal plane, a fourth focal plane, etc.) (e.g., see FIGS. 6C-6D, FIGS. 7C-7D, FIG. 8C, FIGS. 10C-10D, etc.).

In certain embodiments, Step 1700 includes forming a plurality of the wire structures at respective bonding locations of the workpiece, and Step 1702 includes imaging at least a portion of each of the plurality of the wire structures on the wire bonding system (e.g., see FIGS. 8A-8C). In certain of such embodiments, Step 1702 includes simultaneously imaging at least a portion of each of the plurality of the wire structures on the wire bonding system (e.g., see FIGS. 8A-8C).

At Step 1708, a height of the wire structure is determined. In certain of such embodiments, Step 1708 is determined using the results of Step 1702 (e.g., see FIGS. 3A-3B, FIGS. 4A-4B, FIGS. 5A-5B, FIGS. 6A-6D, FIGS. 8A-8C, FIGS. 9C-9D, FIGS. 10A-10D, FIG. 11A, FIG. 11C, FIG. 15, FIG. 16, etc.). In certain of such embodiments, Step 1708 is determined by contacting the free end of the wire structure using a free air ball positioned at an end of a wire bonding tool used to form the wire structure (e.g., see FIGS. 13B-13C).

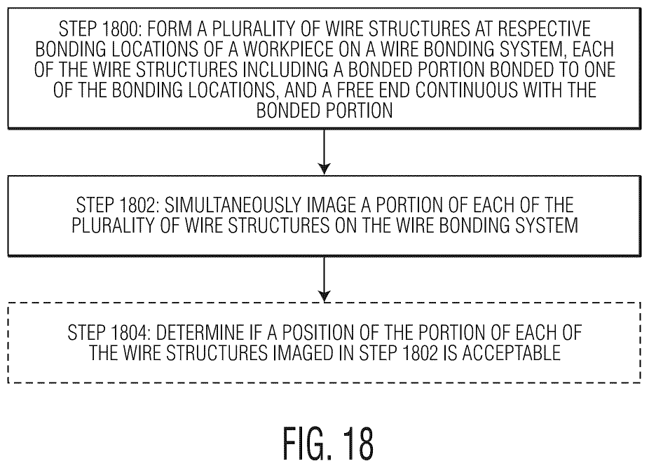

Referring now to FIG. 18, at Step 1800, a plurality of wire structures are formed at respective bonding locations of a workpiece on a wire bonding system (e.g., FIGS. 1A-1B, FIG. 8A, etc.). Each of the wire structures includes a bonded portion bonded to one of the bonding locations, and a free end continuous with the bonded portion. In certain embodiments, Step 1800 is repeated for another workpiece, and wherein for at least one of the plurality of wire structures (or for each of the plurality of wire structures) of the another workpiece an adjustment is made to at least one of (i) a wire bonding parameter and (ii) a wire looping parameter.

At Step 1802, a portion of each of the plurality of wire structures on the wire bonding system is simultaneously imaged. In certain embodiments, Step 1802 includes imaging the free end of each of the plurality of wire structures (e.g., FIGS. 8A-8C). In certain embodiments, Step 1802 includes imaging the bonded portion of each of the plurality of wire structures. In certain embodiments, Step 1802 includes imaging a plurality of portions of each of the plurality of wire structures. In certain embodiments, Step 1802 includes (i) imaging the bonded portion of each of the plurality of wire structures at a first focal plane of an imaging system of the wire bonding system, and (ii) imaging the free end of each of the plurality of wire structures at a second focal plane of the imaging system. In certain embodiments, the plurality of wire structures are included in a single field of view of an imaging system of the wire bonding system (e.g., see FIGS. 8A-8C).

At Step 1804, it is determined if a position of a portion of each of the wire structures imaged in Step 1802 is acceptable.

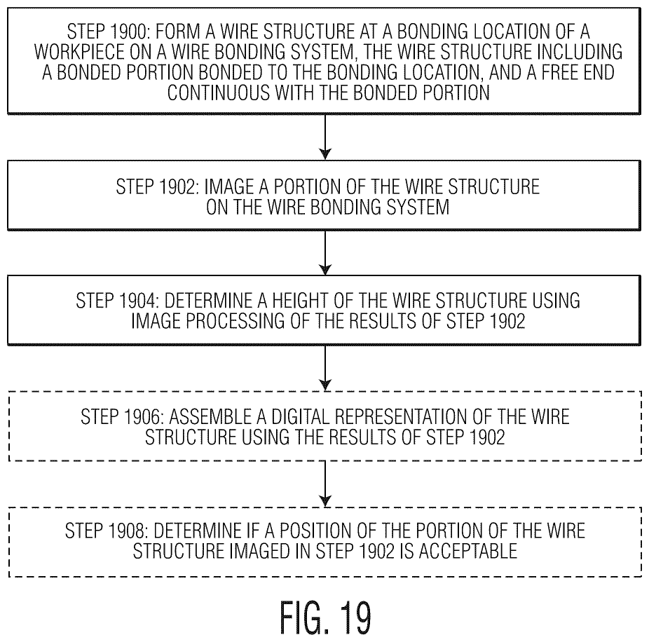

Referring to FIG. 19, At Step 1900, a wire structure is formed at a bonding location of a workpiece on a wire bonding system, the wire structure including a bonded portion bonded to the bonding location, and a free end continuous with the bonded portion. At Step 1902, a portion of the wire structure on the wire bonding system is imaged. At Step 1904, a height of the wire structure is determined using image processing of the results of Step 1902 (e.g., see FIGS. 3A-3B, FIGS. 4A-4B, FIGS. 5A-5B, FIGS. 6A-6D, FIGS. 8A-8C, FIGS. 9A-9D, FIGS. 10A-10D, FIGS. 14A-14B, FIG. 15, FIG. 16, etc.). At optional Step 1906, a digital representation of the wire structure is assembled using the results of Step 1902. At optional Step 1908, it is determined if a position of the portion of the wire structure imaged in Step 1902 is acceptable.

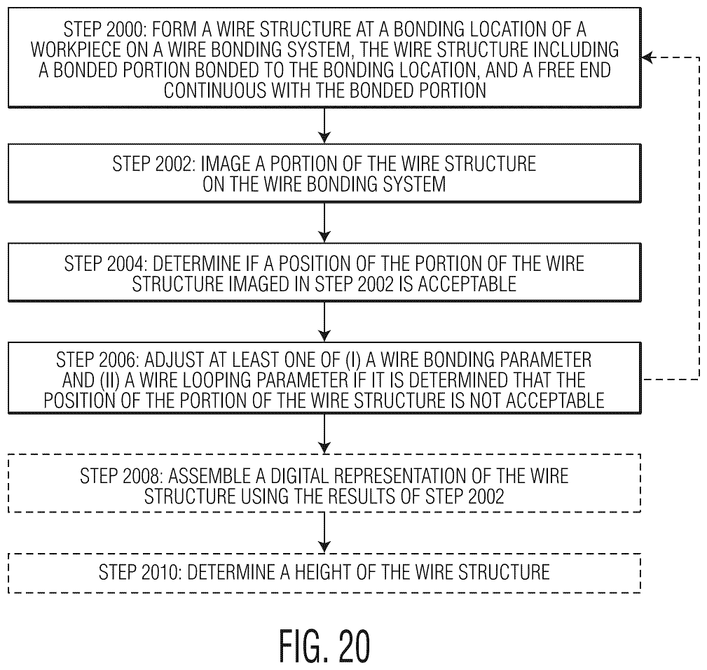

Referring to FIG. 20, At Step 2000, a wire structure is formed at a bonding location of a workpiece on a wire bonding system, the wire structure including a bonded portion bonded to the bonding location, and a free end continuous with the bonded portion. At Step 2002, a portion of the wire structure on the wire bonding system is imaged. At Step 2004, it is determined if a position of the portion of the wire structure imaged in Step 2002 is acceptable (e.g., within an acceptable x-y location range, within an acceptable z position range, within an acceptable 3D position range, within an acceptable bend condition and/or a sway condition of the wire structure, a relative position of one portion of the wire structure relative to another portion is acceptable, etc.). At Step 2006, at least one of (i) a wire bonding parameter and (ii) a wire looping parameter are adjusted if it is determined that the position of the portion of the wire structure is not acceptable (e.g., FIGS. 11A-11C, FIGS. 12A-12C, etc.). It should be understood that in certain embodiments, Step 2000, Step 2002, and Step 2004 may be repeated after Step 2006 (e.g., until it is determined that the position of a portion of a wire structure is acceptable, as illustrated by the dashed arrow). At optional Step 2008, a digital representation of the wire structure is assembled using the results of Step 2002. At optional Step 2010, a height of the wire structure is determined.

In certain embodiments, when it is determined that the position of the wire structure is not acceptable at Step 2006, a wire bonding parameter and/or a wire looping parameter is adjusted and another wire structure is formed at repeated Step 2000 (see the dashed arrow indicating an optionally repeated closed loop). At repeated Step 2002, a portion (e.g., a corresponding/analogous portion with the initial wire structure formed in Step 2000) of the another wire structure is imaged. At repeated Step 2004, a position of the portion of the another wire structure is determined to be acceptable or unacceptable (e.g., using predetermined criteria). Step 2006 may be repeated and, if the position of the portion of the another wire structure is again found to be unacceptable, Step 2000, Step 2002, Step 2004, and/or Step 2006 can be repeated in a closed loop manner until an acceptable condition (e.g., position of a portion of a formed wire structure) is met and/or a predetermined number of iterations of repeated steps have been satisfied. Similarly, optional Steps 2008 and 2010 can be repeated as necessary or as desired in a like manner as repeated Step 2000, Step 2002, Step 2004, and/or Step 2006.

Although the invention is illustrated and described herein with reference to specific embodiments, the invention is not intended to be limited to the details shown. Rather, various modifications may be made in the details within the scope and range of equivalents of the claims and without departing from the invention.

1. A method of imaging a wire structure on a wire bonding system, the method comprising the steps of:
(a) forming the wire structure at a bonding location of a workpiece on the wire bonding system, the wire structure including a bonded portion bonded to the bonding location, and a free end continuous with the bonded portion; and
(b) imaging a portion of the wire structure on the wire bonding system using a plurality of distinct focal planes.

2. The method of claim 1 wherein step (b) includes imaging the free end of the wire structure.

3. The method of claim 1 wherein step (b) includes imaging the bonded portion of the wire structure.

4. The method of claim 1 wherein step (b) includes imaging a plurality of portions of the wire structure, each of the plurality of portions being imaged at a subset of the plurality of distinct focal planes.

5. The method of claim 4 further comprising a step of assembling a digital representation of the wire structure using results of step (b).

6. The method of claim 4 wherein step (b) includes imaging the free end of the wire structure and imaging the bonded portion of the wire structure.

7. The method of claim 6 wherein step (b) includes imaging at least one portion of the wire structure between (i) the bonded portion of the wire structure and (ii) the free end of the wire structure.

8. The method of claim 1 further comprising step (c) determining if a position of the portion of the wire structure imaged in step (b) is acceptable.

9. The method of claim 8 wherein the position of the portion of the wire structure includes an x-y position.

10. The method of claim 8 wherein the position of the portion of the wire structure includes a z-axis position.

11. The method of claim 8 wherein an adjustment is made to at least one of (i) a wire bonding parameter and (ii) a wire looping parameter, if it is determined that the position of the portion of the wire structure is not acceptable at step (c).

12. The method of claim 11 wherein steps (a), (b), and (c) are repeated after the adjustment is made.

13. The method of claim 8 wherein the portion of the wire structure is the free end of the wire structure, and wherein an adjustment is made to a wire looping parameter if it is determined that the position of the free end of the wire structure is not acceptable.

14. The method of claim 8 wherein the portion of the wire structure is the bonded portion of the wire structure, and wherein an adjustment is made to a wire bonding parameter if it is determined that the position of the bonded portion of the wire structure is not acceptable.

15. The method of claim 1 wherein step (b) includes imaging the portion of the wire structure at a first focal plane of the wire bonding system, the first focal plane being coincident with an expected height of the portion of the wire structure.

16. The method of claim 15 wherein step (b) includes imaging the portion of the wire structure at a second focal plane of the wire bonding system if results of imaging of the portion are not acceptable at the first focal plane.

17. The method of claim 1 further comprising a step of determining a height of the wire structure.

18. The method of claim 17 wherein the step of determining the height of the wire structure is determined using results of step (b).

19-22. (canceled)

23. A method of imaging wire structures on a wire bonding system, the method comprising the steps of:
(a) forming a plurality of wire structures at respective bonding locations of a workpiece on the wire bonding system, each of the plurality of wire structures including a bonded portion bonded to one of the bonding locations, and a free end continuous with the bonded portion; and
(b) imaging simultaneously a portion of each of the plurality of wire structures on the wire bonding system.

24-30. (canceled)

31. A method of imaging a wire structure on a wire bonding system, the method comprising the steps of:
(a) forming the wire structure at a bonding location of a workpiece on the wire bonding system, the wire structure including a bonded portion bonded to the bonding location, and a free end continuous with the bonded portion;
(b) imaging a portion of the wire structure on the wire bonding system; and
(c) determining a height of the wire structure using image processing of results of step (b).

32-70. (canceled)
